(19) United States
(12) Patent Application Publication
(10) Pub. No.: US 2024/0407099 A1
(43) Pub. Date: Dec. 5, 2024

(54) ELECTRONIC DEVICES AND METHODS OF MANUFACTURING ELECTRONIC DEVICES

(71) Applicant: Amkor Technology Singapore Holding Pte. Ltd., Singapore (SG)

(72) Inventors: Sang Hyun Jin, Incheon (KR); Ki Yeul Yang, Incheon (KR)

(73) Assignee: Amkor Technology Singapore Holding Pte. Ltd., Singapore (SG)

(21) Appl. No.: 18/326,747

(22) Filed: May 31, 2023

(51) Int. Cl. H05K 1/18; H05K 1/03; H05K 3/46

(52) U.S. Cl. CPC H05K 1/181; H05K 1/0306; H05K 3/4602; H05K 2201/0317; H05K 2201/1031; H05K 2201/10378; H05K 2203/1305

(57) ABSTRACT

In one example, an interposer base can be provided. An inner wall of the interposer base can define an aperture. A liner layer can be provided over the inner wall and the first side of the interposer base. An interposer interconnect can be provided in the aperture. An organic redistribution structure can be provided over the first side of the interposer base and the interposer interconnect. A portion of the interposer base can be removed from the second side to expose the liner layer. An interposer passivation layer can be coupled to the liner layer. A portion of the of the liner layer can be removed to expose the interposer interconnect. An electronic component can be provided over the interposer base to bond a component interconnect of the electronic component to the interposer interconnect. Other examples and related methods are also disclosed herein.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, for example resulting in excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2K show cross-sectional views of an example method for manufacturing an example electronic device.

FIG. 3 shows a cross-sectional view of an example electronic device.

FIGS. 4A to 4D show cross-sectional views of an example method for manufacturing an example electronic device.

FIG. 5 shows a cross-sectional view of an example electronic device.

FIG. 6 shows a cross-sectional view of an example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and/or “including,” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other or describe two elements indirectly coupled by one or more other elements.

### DESCRIPTION

An example method of making an electronic device can comprise providing an interposer base including first side and a second side opposite the first side. An inner wall of the interposer base can define an aperture in the first side. A liner layer can be provided over the inner wall and the first side of the interposer base. An interposer interconnect can be provided in the aperture. A redistribution structure can be provided over the first side of the interposer base and the interposer interconnect. The redistribution structure can comprise an organic material. A portion of the interposer base can be removed from the second side to expose the liner layer. The example method can include providing an interposer passivation layer coupled to the liner layer and located around a sidewall of the interposer interconnect, removing a portion of the of the liner layer to expose the interposer interconnect, and providing an electronic component over the interposer base to bond a component interconnect of the electronic component to the interposer interconnect.

In some examples, the component interconnect can be sputtered onto the electronic component. The component interconnect can have a thickness less than approximately one micrometer. The component interconnect can comprise copper, and the interposer interconnect can comprise copper. A component passivation layer can be provided around a sidewall of the component interconnect and can comprise an inorganic material. The interposer passivation layer can comprise the inorganic material. The component passivation layer can be bonded with the interposer passivation layer. A side of the component interconnect can be recessed from a side of the component passivation layer before providing the electronic component. A portion of the interposer interconnect protruding from the interposer passivation layer can be removed to form an upper side of the interposer interconnect. The upper side of the interposer interconnect can be recessed from the interposer passivation layer. The component interconnect can be coupled to the interposer interconnect by a solderless bond. The liner layer can be between the inner wall of the interposer base and the sidewall of the interposer interconnect. The interposer base can be between the organic material of the redistribution structure and an inorganic material of the interposer passivation layer. A height of the interposer interconnect can be approximately five micrometers above the second side of the interposer base. The interposer base can comprise silicon or glass.

An example electronic device can comprise an interposer base including inner walls defining openings through the interposer base. A liner layer can be located on the inner walls and a first surface of the interposer base. Interposer interconnects can be located in the openings and coupled to the liner layer. The interposer interconnects can protrude from a first side of the interposer base. A first electronic component can comprise component interconnects bonded to the interposer interconnects. An interposer passivation layer can be located on the first side of the interposer base and around the interposer interconnects. A redistribution structure can be located on a second side of the interposer base opposite the first side. The redistribution structure can comprise an organic material and can be coupled to the interposer interconnects. The interposer base can comprise silicon or glass. The component interconnects can have a height less than approximately one micrometer from a side of the first electronic component. A first interposer interconnect of the interposer interconnects can protrudes less than approximately five micrometers from the first side of the interposer base. The interposer passivation layer can be located around the component interconnects and around the interposer interconnects. The liner layer can be between the inner walls of the interposer base and sidewalls of the interposer interconnects. A thickness of the redistribution structure can be greater than a thickness of the interposer base. A second electronic component can be coupled to the interposer base, and an encapsulant can be located around the first electronic component and the second electronic component.

Other examples are included in the present disclosure. Such examples may be found in the figures, in the claims, or in the description of the present disclosure.

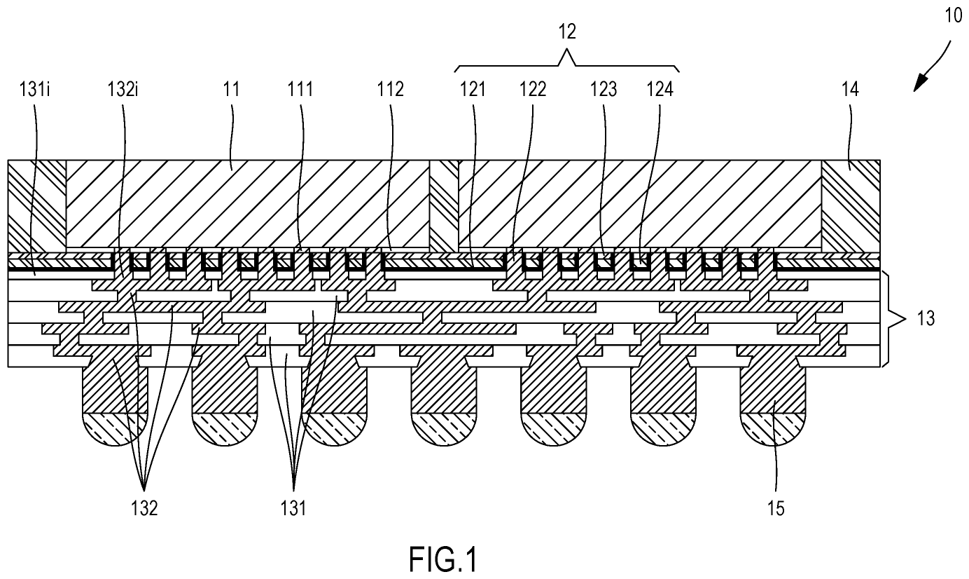

FIG. 1 shows a cross-sectional view of an example electronic device 10. In the example shown in FIG. 1, electronic device 10 can comprise electronic component 11, interposer 12, redistribution structure 13, encapsulant 14, and external interconnects 15. Hybrid bonding techniques described herein are used to couple interposer 12 to electronic component 11.

Various examples of electronic component 11 can comprise component interconnects 111 and component passivation layer 112. Interposer 12 can comprise liner layer 121, interposer interconnects 122, interposer passivation layer 123, and interposer base 124. Interposer base 124 can also be referred to as a substrate or wafer. Redistribution structure 13 can comprise dielectric structure 131 and conductive structure 132.

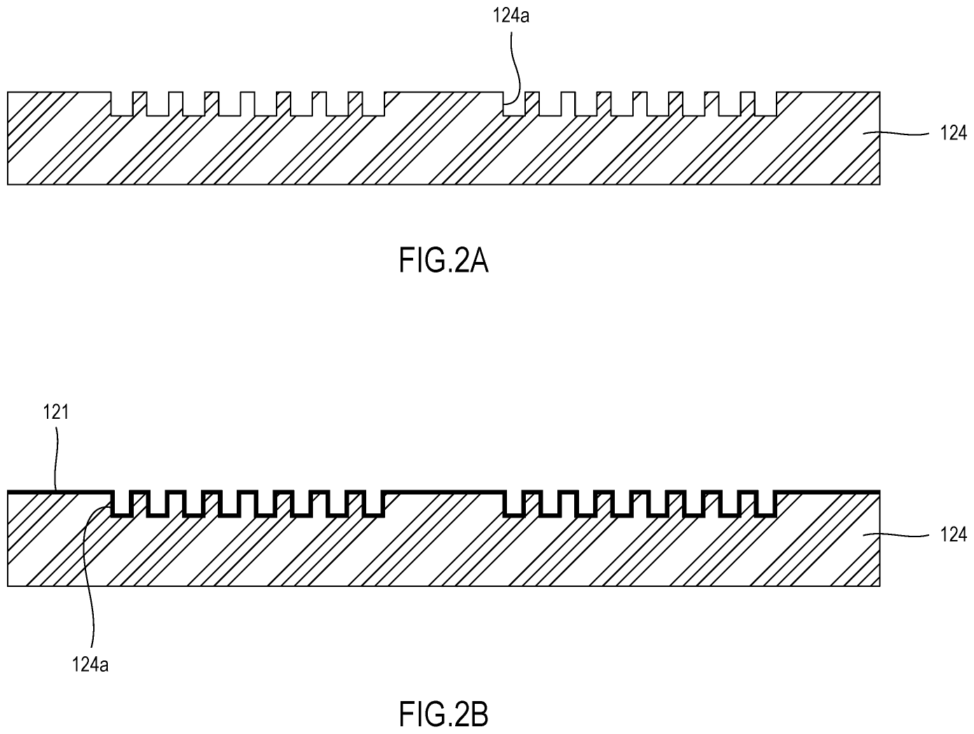

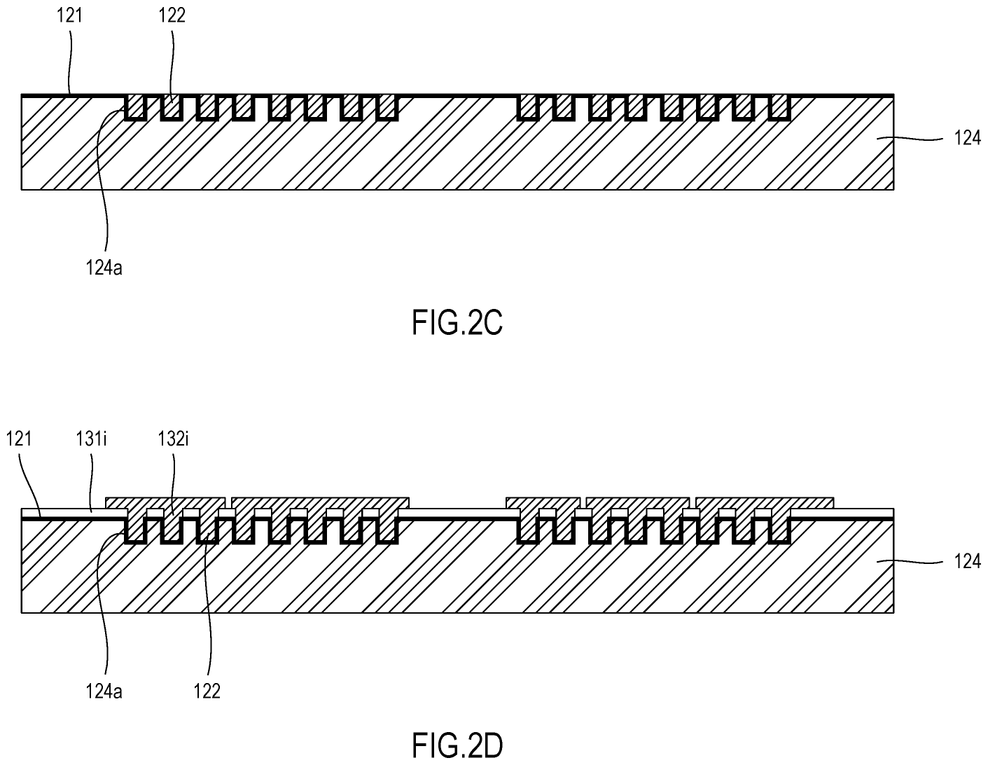

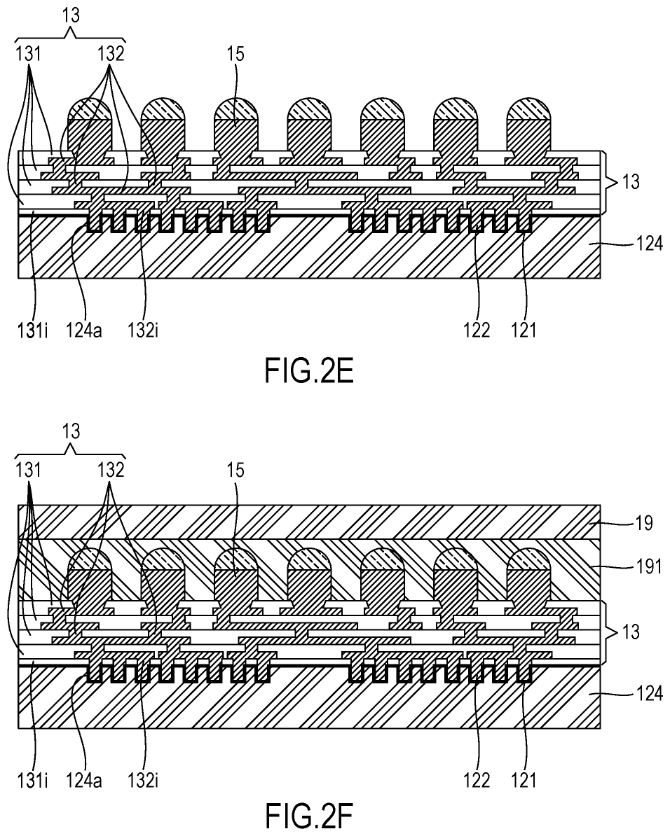

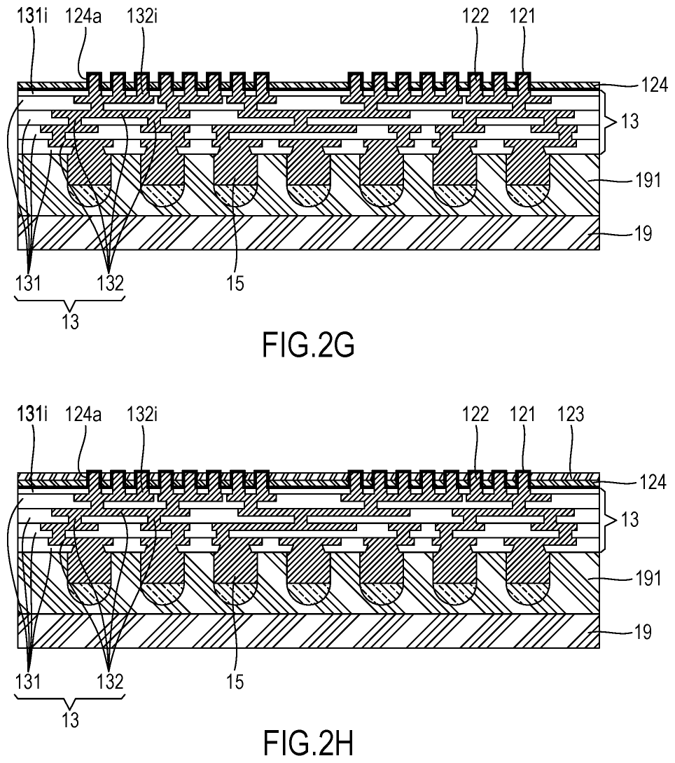

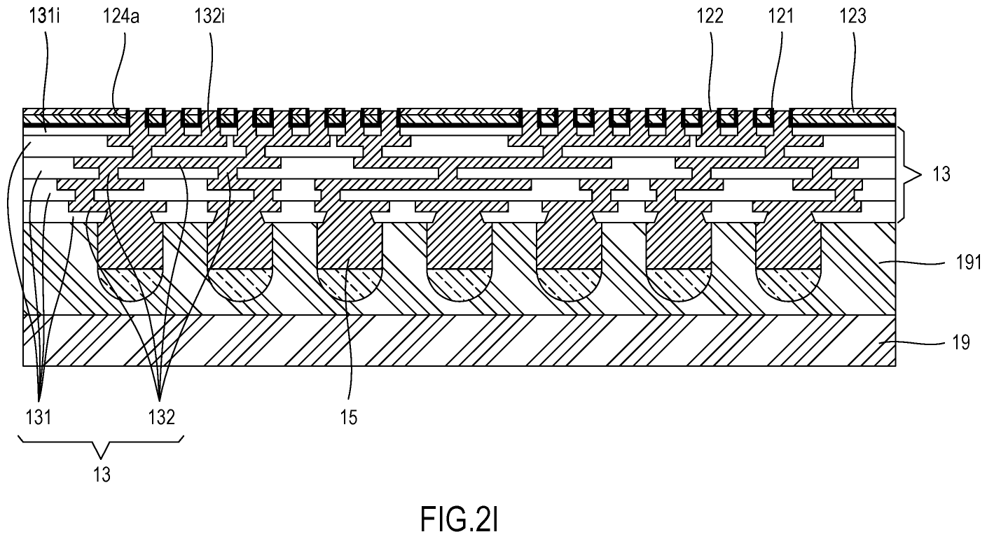

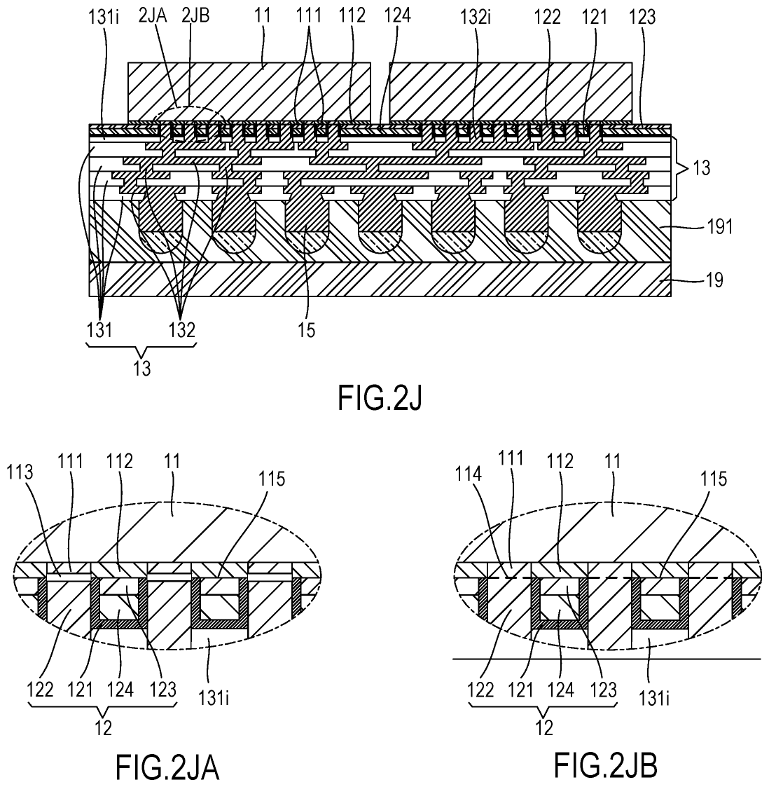

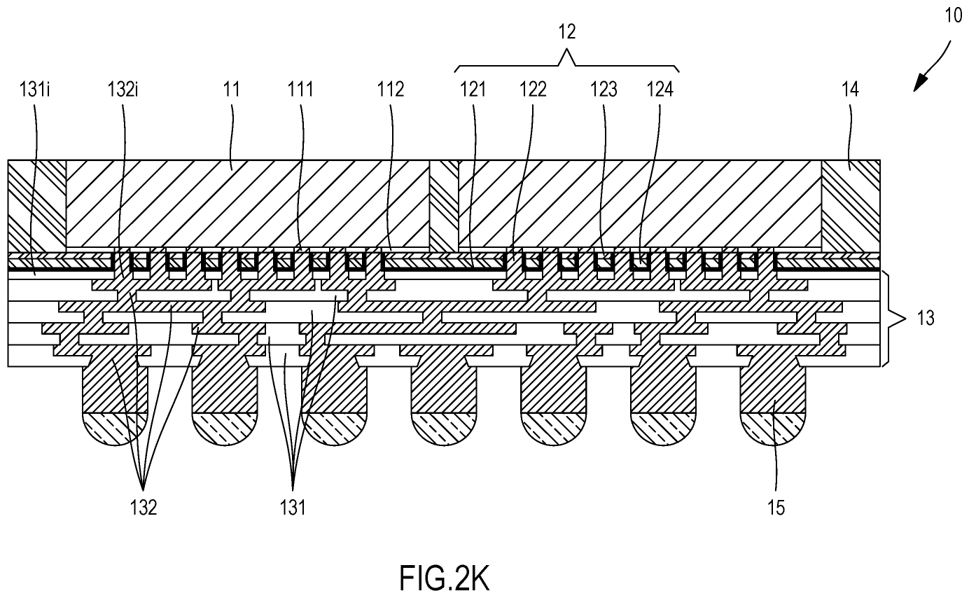

FIGS. 2A to 2K show cross-sectional views of an example method for manufacturing an example electronic device 10. FIG. 2A shows electronic device 100 at an early stage of manufacture. In the example of FIG. 2A, by removing a certain depth from the top of interposer base 124, aperture 124a can be provided. One or more apertures 124a can be provided on the upper side of interposer base 124 so as to be spaced apart from each other in a matrix form having rows or columns. For example, apertures 124a can be provided by removing exposed regions through etching after forming a mask pattern on the upper side of interposer base 124. In some examples, apertures 124a can comprise or be referred to as or comprise openings or grooves. Apertures 124a can have a depth ranging from approximately 0.5 micrometers (μm) to 100 μm and a width ranging from approximately 0.5 μm to 100 μm. As used herein to describe distance, the term approximately can mean +/−5%, +/−10%, +/−15%, or +/−20%.

In some examples, interposer base 124 can be a substantially planar plate. Interposer base 124 can comprise or be referred to as a base or a body. For example, interposer base 124 can be made of a silicon wafer or glass. In some examples, interposer base 124 can have a thickness ranging from approximately 50 μm to 2000 μm and a width ranging from approximately 100 mm to 300 millimeters (mm). Interposer base 124 serves to integrally support multiple components in the process of providing electronic component 11, interposer base 124, redistribution structure 13, and external interconnects 15.

FIG. 2B shows electronic device 10 at a later stage of manufacture. In the example shown in FIG. 2B, liner layer 121 can be provided to uniformly cover the upper side of interposer base 124 and the interior portions of apertures 124a. Liner layer 121 can be provided to cover the upper side of interposer base 124 and inner walls that define apertures 124a. When interposer base 124 is made of a silicon wafer, liner layer 121 can be provided to prevent electrical conduction between interposer interconnect 122 and interposer base 124. When interposer base 124 is made of glass, the step of providing liner layer 121 can be omitted. In some examples, liner layer 121 can comprise or be referred to as a dielectric layer, an insulating layer, SiO2, SiN, or Al3O2. For example, liner layer 121 can be in a three-layered structure having a dielectric layer (e.g., SiO2, SiN, or Al3O2), a barrier layer (e.g., a Ti or Ta layer), and a seed layer (e.g., a Cu seed layer). In some examples, liner layer 121 can be provided by deposition or coating. In some examples, liner layer 121 can have a thickness ranging from approximately 0.1 μm to 10 μm.

FIG. 2C shows electronic device 10 at a later stage of manufacture. In the example shown in FIG. 2C, interposer interconnects 122 can be provided to fill apertures 124a of interposer base 124. In some examples, interposer interconnects 122 can be provided by plating or sputtering. For example, interposer interconnects 122 can be provided to fill apertures 124a by using a seed layer as a seed, after forming a seed layer. For example, interposer interconnects 122 can be provided to fill apertures 124a by sputtering, after providing mask pattern to cover the upper side of interposer base 124. The upper sides of interposer interconnects 122 can be coplanar with the upper side of interposer base 124 or liner layer 121. Interposer interconnects 122 can comprise or be referred to as through vias, TSVs, conductive posts, conductive pillars, or conductive vias. In some examples, liner layer 121 can be interposed between interposer interconnects 122 and the inner walls that define apertures 124a. For example, interposer interconnects 122 can comprise copper, gold, silver, or nickel. In some examples, interposer interconnects 122 can have a height ranging from approximately 0.5 μm to 100 μm. In some examples, interposer interconnects 122 can have a width and a pitch each ranging from approximately 0.5 μm to 100 μm, where a fine pitch can be implemented.

FIG. 2D shows electronic device 10 at a later stage of manufacture. In the example shown in FIG. 2D, inner dielectric layer 131i and inner conductive layer 132i can be sequentially provided on the upper side of interposer base 124.

In some examples, inner dielectric layer 131i can be in contact with the upper side of interposer base 124 and interposer interconnects 122. After providing inner dielectric layer 131i, openings can be provided to expose interposer interconnects 122. For example, after forming a mask pattern on the upper side of interposer base 124, the openings of inner dielectric layer 131i can be provided by removing exposed interposer base 124 through etching. In some examples, openings of interposer base 124 can comprise or be referred to as apertures or holes. Inner dielectric layer 131i can comprise an electrically insulating material such as polymer, polyimide (PI), benzocyclobutene (BCB), polybenzoxazole (PBO), bismaleimide triazine (BT), Ajinomoto Buildup Film (ABF), or resin. Inner dielectric layer 131i can be provided by spin coating, spray coating, dip coating, or rod coating. Inner dielectric layer 131i can have a thickness ranging from approximately 0.5 μm to 50 μm.

Inner conductive layer 132i can be provided on the upper side of inner dielectric layer 131i. Inner conductive layer 132i can be in contact with and electrically connected to interposer interconnects 122 through the openings of inner dielectric layer 131i. Inner conductive layer 132i can be provided to partially cover the upper side of inner dielectric layer 131i, to fill the openings of inner dielectric layer 131i, and to make patterns. Inner conductive layer 132i can comprise or be referred to as traces, pads, vias, conductive paths, wiring patterns, circuit patterns, redistribution layers (RDLs), or under-bump-metallurgies (UBMs). In some examples, inner conductive layer 132i can comprise copper, iron, nickel, gold, silver, palladium, or tin. In some examples, inner conductive layer 132i can have a thickness ranging from approximately 0.5 μm to 100 μm.

FIG. 2E shows electronic device 10 at a later stage of manufacture. In the example of FIG. 2E, redistribution structure 13 and external interconnects 15 can be provided on the upper sides of inner dielectric layer 131i and inner conductive layer 132i.

In some examples, redistribution structure 13 can comprise dielectric structure 131 and conductive structure 132. Dielectric structure 131 can comprise one or more dielectric layers. Dielectric structure 131 can comprise corresponding elements, features, materials, or manufacturing methods similar to those of inner dielectric layer 131i. Dielectric structure 131 can comprise inner dielectric layer 131i, and the dielectric layer in contact with interposer base 124 in dielectric structure 131 can comprise or be referred to as inner dielectric layer 131i.

In some examples, conductive structure 132 can comprise one or more conductive layers defining a signal distribution element. In redistribution structure 13, one or more layers or elements of conductive structure 132 can be interleaved with dielectric structure 131. Conductive structure 132 can comprise corresponding elements, features, materials, or manufacturing methods similar to those of inner conductive layer 132i. Conductive structure 132 can comprise inner conductive layer 132i, and, in conductive structure 132, the conductive layer in contact with interposer interconnects 122 can comprise or be referred to as inner conductive layer 132i.

In some examples, redistribution structure 13 can comprise or be referred to as an RDL substrate, a buildup substrate, a coreless substrate, or a fine-pitch substrate. Redistribution structure 13 can have a total thickness ranging from approximately 1 μm to 100 μm. In some examples, redistribution structure 13 can have a thickness greater than interposer base 124.

In some examples, redistribution structure 13 can be a redistribution layer (“RDL”) substrate. RDL substrates can comprise one or more conductive redistribution layers and one or more dielectric layers and (a) can be formed layer by layer over an electronic device to where the RDL substrate is to be coupled, or (b) can be formed layer by layer over a carrier and can be entirely removed or at least partially removed after the electronic device and the RDL substrate are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process and can include one or more dielectric layers alternatingly stacked with one or more conductive layers and define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise a conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process, and can include a photolithographic mask through where light is exposed to photo-pattern desired features such as vias in the dielectric layers. The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of inorganic dielectric layer(s) can comprise silicon nitride (Si3N4), silicon oxide (SiO2), and/or SiON. The inorganic dielectric layer(s) can be formed by growing the inorganic dielectric layers using an oxidation or nitridization process instead using photo-defined organic dielectric materials. Such inorganic dielectric layers can be filler-fee, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can comprise or be referred to as a coreless substrate. Other substrates in this disclosure can also comprise an RDL substrate.

In some examples, redistribution structure 13 can be a pre-formed substrate. The pre-formed substrate can be manufactured prior to attachment to an electronic device and can comprise dielectric layers between respective conductive layers. The conductive layers can comprise copper and can be formed using an electroplating process. The dielectric layers can be relatively thicker non-photo-definable layers and can be attached as a pre-formed film rather than as a liquid and can include a resin with fillers such as strands, weaves, and/or other inorganic particles for rigidity and/or structural support. Since the dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can be a coreless substrate and omits the permanent core structure, and the dielectric and conductive layers can be formed on a sacrificial carrier and is removed after formation of the dielectric and conductive layers and before attachment to the electronic device. The pre-formed substrate can be referred to as a printed circuit board (PCB) or a laminate substrate. Such pre-formed substrate can be formed through a semi-additive or modified-semi-additive process. Other substrates in this disclosure can also comprise a pre-formed substrate.

External interconnects 15 can be in contact with and electrically connected to conductive structure 132 of redistribution structure 13. External interconnects 15 can be in contact with conductive structure 132 exposed through the openings of dielectric structure 131. In some examples, external interconnects 15 can comprise tin (NS), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. For example, external interconnects 15 can be provided through a reflow process after forming a solder-containing conductive material on conductive structure 132 through a ball-drop process. External interconnects 15 can comprise or be referred to as conductive balls such as solder balls, conductive pillars such as copper pillars, or conductive posts having solder caps on copper pillars. In some examples, external interconnects 15 can have a size ranging from approximately 1 μm to 1000 μm. In some examples, external interconnects 15 can comprise or be referred to as external input/output terminals of electronic device 10.

FIG. 2F shows electronic device 10 at a later stage of manufacture. In the example shown in FIG. 2F, carrier 19 can be provided to cover the upper side of redistribution structure 13 and external interconnects 15.

Carrier 19 can be a substantially planar plate. In some examples, carrier 19 can comprise or be referred to as a wafer, a board, a panel, or a strip. In some examples, carrier 19 can comprise silicon, glass, metal, or an organic material. Carrier 19 can have a thickness ranging from approximately 50 μm to 2000 μm and a width ranging from approximately 100 mm to 300 mm. Carrier 19 can provide support during future steps including removal of portions of interposer base 124. Carrier 19 can support electronic device 10 before encapsulant 14 is provided.

Temporary bond layer 191 can be interposed between carrier 19 and the upper side of redistribution structure 13 and between carrier 19 and the outer surfaces of external interconnects 15. For example, temporary bond layer 191 can be provided on the surface of carrier 19. The upper side of redistribution structure 13 and the outer surfaces of external interconnects 15 can be attached to carrier 19 by temporary bond layer 191. In some examples, temporary bond layer 191 can be provided on the surface of carrier 19 by: coating such as spin coating, doctor blade, casting, painting, spray coating, slot die coating, curtain coating, slide coating, or knife over edge coating; printing such as screen printing, pad printing, gravure printing, flexography printing, or offset printing; inkjet printing, which is an intermediate technology between coating and printing; or direct attachment of an adhesive film or an adhesive tape. In some examples, after being provided to the upper side of redistribution structure 13 and the outer surfaces of external interconnects 15, temporary bond layer 191 can be attached to carrier 19. For example, temporary bond layer 191 can be a thermal release tape (film) or an optical release tape (film), the adhesive strength is weakened or removed by heat or light. In some examples, the adhesive strength of temporary bond layer 191 can be weakened or removed by physical or chemical external forces. Electronic device 10 having carrier 19 attached can be flipped so carrier 19 is located on the lower side and electronic device 10 is located on the upper side.

FIG. 2G shows electronic device 10 at a later stage of manufacture. In the example shown in FIG. 2G, liner layer 121 can be exposed by removing the upper side of interposer base 124. Liner layer 121 can cover interposer interconnects 122, and interposer interconnects 122 and liner layer 121 can upwardly protrude from interposer base 124. For example, after a partial upper portion of interposer base 124 is removed by grinding, the upper portion of interposer base 124 can be removed through etching, and liner layer 121 covering interposer interconnects 122 can be exposed or protruding. The height of interposer interconnects 122 and liner layer 121 protruding from the upper side of interposer base 124 can range from approximately 0.5 μm to 100 μm.

FIG. 2H shows electronic device 10 at a later stage of manufacture. In the example shown in FIG. 2H, interposer passivation layer 123 can be provided to cover the upper side of interposer base 124. Interposer passivation layer 123 can be in contact with the upper side of interposer base 124. Interposer passivation layer 123 can expose interposer interconnects 122 and liner layer 121. Interposer interconnects 122 and liner layer 121 can upwardly protrude, compared to interposer passivation layer 123. In some examples interposer passivation layer 123 can be provided by deposition or coating. In some examples, interposer passivation layer 123 can comprise or be referred to as a dielectric layer, an oxide film, or a nitride film. For example, interposer passivation layer 123 can be SiO2 SiCN, SiN, or Al2O3. In some examples, interposer passivation layer 123 can have a thickness ranging from approximately 0.1 μm to 100 μm. Interposer 12 can comprise interposer base 124, liner layer 121, interposer interconnects 122, and interposer passivation layer 123. In some examples, interposer 12 can have a total thickness ranging from approximately 0.5 μm to 100 μm. Since interposer base 124 is made of silicon or glass, surface planarization of interposer 12 can be facilitated. Interposer 12 can include only interposer interconnects 122 without a pad, and thus the total thickness can be reduced.

FIG. 2I shows electronic device 10 at a later stage of manufacture. In the example shown in FIG. 2I, upper portions of interposer interconnects 122 and liner layer 121 can be removed. Interposer interconnects 122 and liner layer 121 that upwardly protrude compared to interposer passivation layer 123 can be removed by grinding or by chemical mechanical polishing (CMP). Liner layer 121 covering the upper sides of interposer interconnects 122 can be removed, and the upper sides of interposer interconnects 122 can be exposed. The upper sides of interposer interconnects 122 can be recessed relative to the upper side of interposer passivation layer 123 by a thickness of approximately 1 μm to approximately 5 μm. The upper side of interposer passivation layer 123 can be proud relative to the upper sides of interposer interconnects 122. The upper side of interposer passivation layer 123 can protrude from the upper sides of interposer interconnects 122. Liner layer 121 can be interposed between interposer interconnects 122 and interposer passivation layer 123, between interposer interconnects 122 and interposer base 124, and between interposer base 124 and dielectric structure 131 of redistribution structure 13.

FIG. 2J shows electronic device 10 at a later stage of manufacture. FIG. 2JA is an enlarged view showing a portion 2JA of FIG. 2J. In the example shown in FIGS. 2J and 2JA, electronic component 11 can be provided over interposer interconnects 122 and interposer passivation layer 123.

Electronic component 11 can comprise component interconnects 111 and component passivation layer 112 on the lower side. In some examples, the lower side of electronic component 11 can comprise or be referred to as an active side. Component interconnects 111 can be provided on the lower side of electronic component 11 so as to be spaced apart from each other in rows or columns. Component interconnects 111 can comprise or be referred to as Cu pads, Cu pillars, or Cu posts. Component interconnects 111 can be input/output terminals of electronic component 11. In some examples, component interconnects 111 can be provided on the lower side of electronic component 11 by electrolytic plating, electroless plating, sputtering, PVD, CVD, MOCVD, ALD, LPCVD, or PECVD. For example, after providing a photoresist pattern for exposing bond pads of electronic component 11, component interconnects 111 can be provided to be in contact with exposed bond pads. Component interconnects 111 can have a thickness ranging from approximately 0.1 μm to 10 μm and a width and a pitch each ranging from approximately 0.1 μm to 100 μm. For example, component interconnects 111 can include CuP sputtered onto electronic component 11 less than approximately 1 μm thick.

Component passivation layer 112 of electronic component 11 can be in contact with the lower side of electronic component 11 and sidewalls of component interconnects 111. In some examples, the lower side of component passivation layer 112 and the lower sides of component interconnects 111 can be coplanar. In some examples, the lower sides of component interconnects 111 can be recessed from the lower side of component passivation layer 112. In some examples component passivation layer 112 can be provided by deposition or coating. Component passivation layer 112 can comprise corresponding elements, features, materials, or manufacturing methods similar to those of interposer passivation layer 123. Component passivation layer 112 can have a similar thickness to component interconnects 111.

In some examples, pick-and-place equipment can pick up electronic component 11 to place it on interposer 12. Component interconnects 111 of electronic component 11 can be located on interposer interconnects 122 of interposer 12, and component passivation layer 112 of electronic component 11 can be located on interposer passivation layer 123. Next, component passivation layer 112 of electronic component 11 can be bonded to interposer passivation layer 123 through a reflow or thermal compression process, and component interconnects 111 of electronic component 11 can be in contact with or be bonded to interposer interconnects 122.

In some examples, electronic component 11 and interposer 12 can be subjected to hybrid bonding. Before bonding, component passivation layer 112 and interposer passivation layer 123 can be subjected to surface activation through a plasma in a vacuum. Component passivation layer 112 and interposer passivation layer 123 can be bonded at a low temperature due to surface activation. Component passivation layer 112 and interposer passivation layer 123 can exert a pulling force towards one another and urge component interconnects 111 towards interposer interconnects 122. Grain growth may occur across the boundary between component interconnects 111 and interposer interconnects 122 to form direct bond 114. Component interconnects 111 towards interposer interconnects 122 contact one another in response to the example hybrid bonding process of FIG. 2K. Electronic device 10 can be bonded to component interconnects 111 and interposer interconnects 122 to implement a fine-pitch interconnection.

In some examples, electronic component 11 can comprise or be referred to as a die, a chip, or a package. In some examples, the total thickness of electronic component 11 can range from approximately 50 μm to 800 μm, and the area can range from approximately 0.5 mm×0.5 mm to approximately 70 mm×70 mm.

In some examples, gap or void 113 is defined between component interconnects 111 and interposer interconnects 122 when electronic component 11 is initially placed over interposer base 124. Void 113 closes during bonding as component interconnect 111 and interposer interconnect 122 are urged together or expand towards each other. Some examples can include application of heat or pressure to close void 113. Respective activated surfaces of component passivation layer 112 and interposer passivation layer 123 can be placed in contact with each other to establish passivation bond 115 that secures component passivation layer 112 with interposer passivation layer 123. In some examples, passivation bond 115 can initially start as a Van der Waals bond that progresses to a covalent bond through time or temperature. With passivation bond 115 secured, component interconnect 111 and interposer interconnect 122 can be urged towards each other until void 113 is closed and direct bond 114 is established. In some examples, direct bond 114 can comprise or be referred as a fusion bond or a solderless bond. In some examples, direct bond 114 can comprise grain growth of the material of interconnects 111, 122 into each other. In some examples, direct bond 114 can be established by pressure from component interconnect 111 and interposer interconnect 122 expanding towards each other due to heat while secured by passivation bond 115, or by pressure from passivation bond 115 attracting the passivation layers 112,123 onto each other and thereby compressing interconnects 111,112 onto each other.

FIG. 2JB shows electronic device 10 at a later stage of manufacture. FIG. 2JB is an enlarged view showing a portion 2JB of FIG. 2J. In the example shown in FIGS. 2J and 2JB, component interconnects 111 can be bonded to interposer interconnects 122. Component interconnects 111 can be bonded by direct bond 114 with interposer interconnects 122.

FIG. 2K shows electronic device 10 at a later stage of manufacture. In the example shown in FIG. 2K, encapsulant 14 can be provided to cover electronic component 11 and interposer 12. Encapsulant 14 can be in contact with the lateral sides of electronic component 11 and the upper side of interposer passivation layer 123.

In some examples, the upper side of electronic component 11 can be exposed to the upper portion of encapsulant 14. In some examples, encapsulant 14 can comprise or be referred to as a body or a molding. For example, encapsulant 14 can comprise an epoxy mold compound, a resin, an organic polymer with inorganic fillers, a curing agent, a catalyst, a coupling agent, a colorant, or a flame retardant, and can be formed by compression molding, transfer molding, liquid body molding, vacuum lamination, paste printing, or film assist molding. In some examples, encapsulant 14 can be provided to cover the upper side and sidewalls of electronic component 11 and the upper side of interposer passivation layer 123, and the upper portion can then be removed to expose the upper side of electronic component 11. The upper portion of encapsulant 14 can be removed, and thus heat dissipation of electronic component 11 can be facilitated and the size of electronic device 10 can be reduced.

For example, the upper portion of encapsulant 14 can be removed by a conventional grinding or chemical etching process. Encapsulant 14 can have a thickness ranging from approximately 100 μm to 1000 μm. Encapsulant 14 can protect electronic component 11 from external factors.

After forming encapsulant 14, carrier 19 can be separated from redistribution structure 13 and external interconnects 15. Temporary bond layer 191 can be separated from redistribution structure 13 and external interconnects 15 while remaining attached to carrier 19. Heat, light, chemical solution, or physical external force can be applied to remove or reduce the adhesive strength of temporary bond layer 191 of carrier 19, and carrier 19 can be separated from redistribution structure 13 and external interconnects 15. Accordingly, the lower side of redistribution structure 13 and external interconnects 15 can be exposed. In some examples, a singulation process of sawing interposer 12, redistribution structure 13, and encapsulant 14 to separate it into electronic device 10 can be performed. In some examples, the singulation process can be performed by using a diamond blade or laser beam.

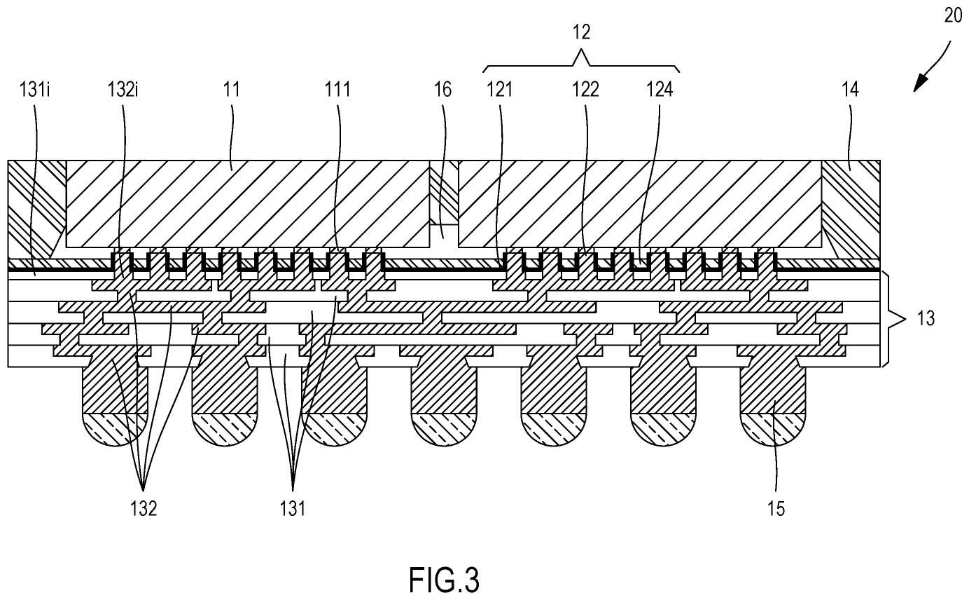

FIG. 3 shows a cross-sectional view of an example electronic device 20. In the example shown in FIG. 3, electronic device 20 can comprise electronic component 11, interposer 12, redistribution structure 13, encapsulant 14, external interconnects 15, and underfill 16.

Electronic device 20 can be similar to electronic device 10 described above. For example, electronic device 20 can be similar to electronic device 10 in terms of redistribution structure 13, encapsulant 14, and external interconnects 15. Electronic device 20 can comprise underfill 16. In electronic device 20, electronic component 11 can comprise component interconnects 111. In electronic device 20, interposer 12 can comprise liner layer 121, interposer interconnects 122, and interposer base 124.

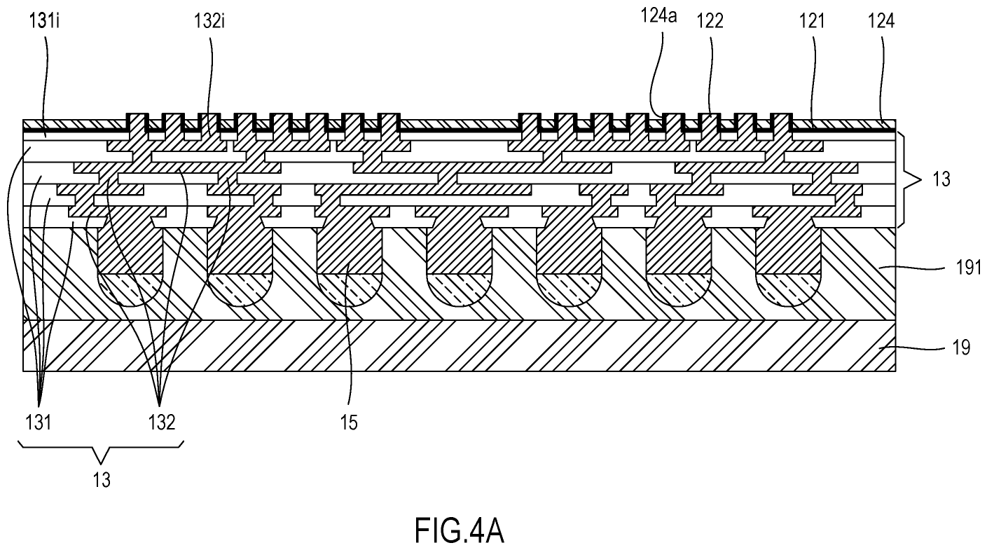

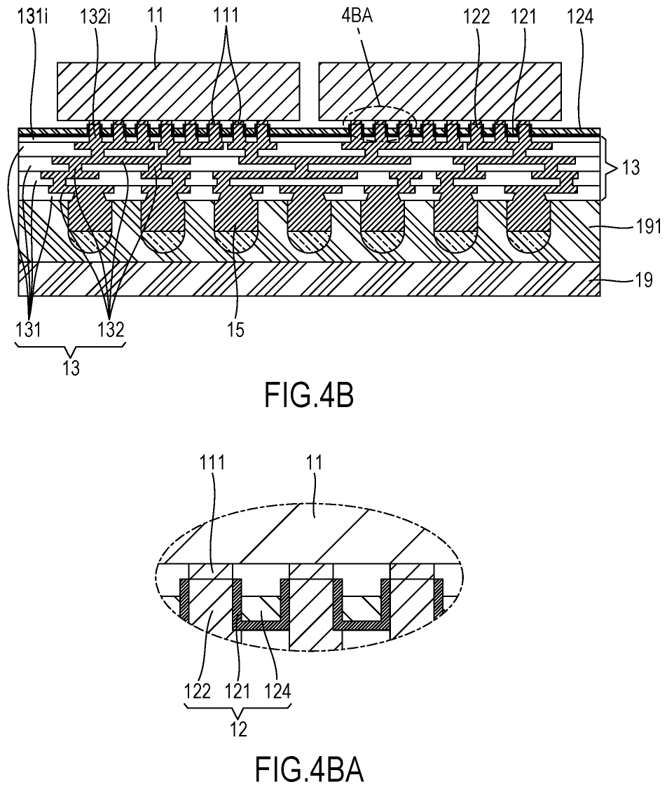

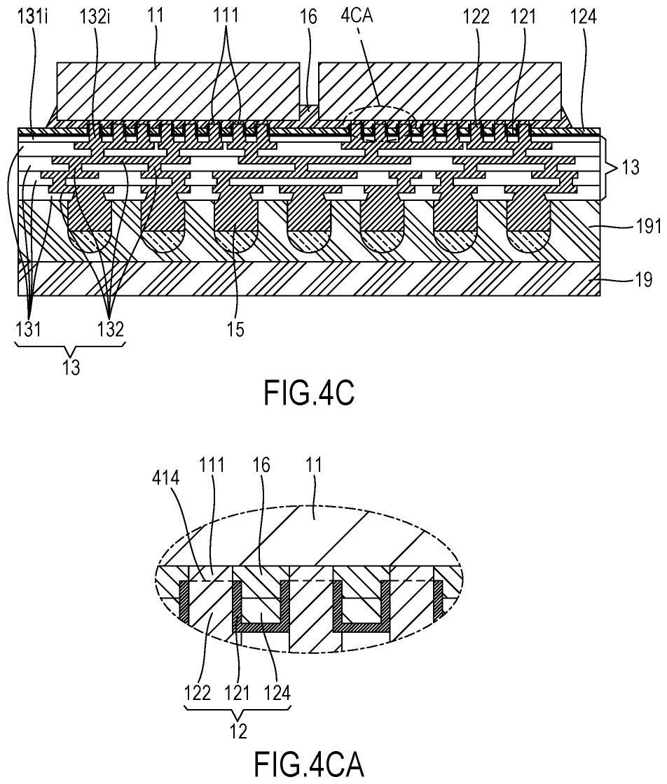

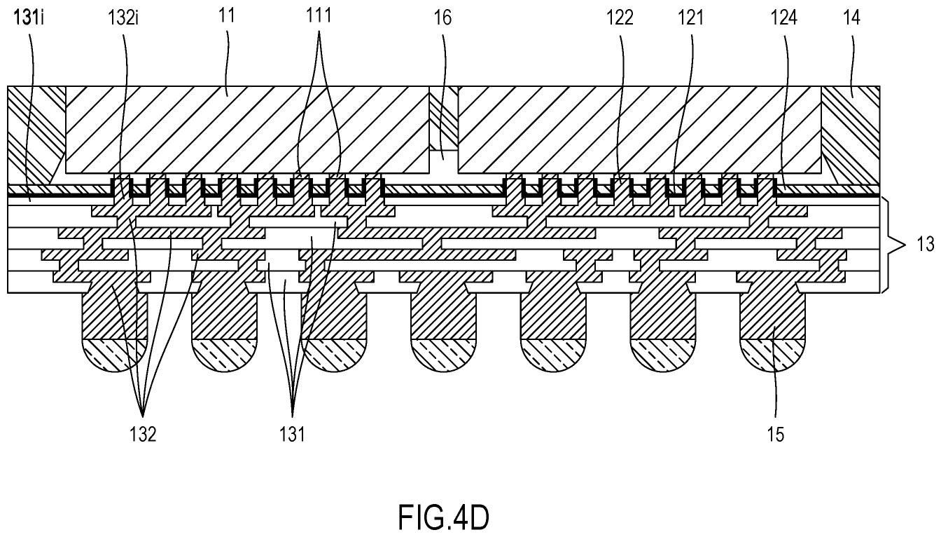

FIGS. 4A to 4D show cross-sectional views of an example method for manufacturing an example electronic device 20. The process step illustrated in FIG. 4A is performed after steps similar to or the same as the steps described and illustrated in FIGS. 2A through 2G.

FIG. 4A shows electronic device 20 at a later stage of manufacture. In the example shown in FIG. 4A, by removing liner layer 121 covering the upper sides of interposer interconnects 122, the upper sides of interposer interconnects 122 can be exposed. By removing liner layer 121 covering a portion of the lateral sides of interposer interconnects 122, the lateral sides of interposer interconnects 122 can be exposed. For example, after forming a mask pattern on the upper side of interposer base 124, exposed liner layer 121 can be removed through etching. The mask pattern can be provided to be in contact with liner layer 121 covering the upper side of interposer base 124 and sidewalls of interposer interconnects 122. Liner layer 121 can cover the sidewalls of interposer interconnects 122 and can be interposed between interposer base 124 and interposer interconnects 122 and between interposer base 124 and redistribution structure 13.

FIG. 4B shows electronic device 20 at a later stage of manufacture. FIG. 4BA is an enlarged view illustrating a portion 4BA of FIG. 4B. In the example shown in FIGS. 4B and 4BA, electronic component 11 can be provided on the surface of interposer 12.

Electronic component 11 can comprise component interconnects 111 on the lower side. In some examples, the lower side of electronic component 11 can comprise or be referred to as a component active side. Component interconnects 111 can be provided on the lower side of electronic component 11 so as to be spaced apart from each other in a row or column direction. Component interconnects 111 can comprise or be referred to as Cu pads, Cu pillars, or Cu posts. Component interconnects 111 can be input/output terminals of electronic component 11. In some examples, component interconnects 111 can be provided on the lower side of electronic component 11 by electrolytic plating, electroless plating, sputtering, PVD, CVD, MOCVD, ALD, LPCVD, or PECVD. For example, after providing a photoresist pattern for exposing bond pads of electronic component 11, component interconnects 111 can be provided to be in contact with exposed bond pads. In some examples, component interconnects 111 can have a thickness ranging from approximately 0.1 μm to 10 μm and a width and a pitch each ranging from approximately 0.1 μm to 100 μm.

In some examples, pick-and-place equipment can pick up electronic component 11 to place it on interposer 12. Component interconnects 111 of electronic component 11 can be located on interposer interconnects 122 of interposer 12. Component interconnects 111 of electronic component 11 can be in contact with and be bonded to interposer interconnects 122 through a reflow or thermal compression process. Electronic device 10 can be bonded to component interconnects 111 and interposer interconnects 122, and thus a fine pitch can be implemented and electrical performance can be improved.

Interposer 12 can comprise interposer base 124, liner layer 121, and interposer interconnects 122. In some examples, interposer 12 can have a total thickness ranging from approximately 0.5 μm to 100 μm. Since interposer base 124 is made of silicon or glass, surface planarization of interposer 12 can be facilitated. Interposer 12 can include interposer interconnects 122 without a pad, and thus the total thickness can be reduced.

In some examples, electronic component 11 can comprise or be referred to as a die, a chip, or a package. In some examples, electronic component 11 can have a total thickness ranging from approximately 50 μm to 800 μm and an area ranging from approximately 0.5 mm×0.5 mm to approximately 70 mm×70 mm.

FIG. 4C shows electronic device 20 at a later stage of manufacture. FIG. 4CA is an enlarged view of a portion 4CA of FIG. 4C. In the example shown in FIGS. 4C and 4CA, underfill 16 can be located between electronic component 11 and interposer 12. Underfill 16 can be in contact with the lower side of electronic component 11 and the upper side of interposer 12. In some examples, underfill 16 can be in contact with component interconnects 111, liner layer 121, and interposer interconnects 122. Underfill 16 can comprise or be referred to as a dielectric layer or a non-conductive paste, and can be free of inorganic fillers. In some examples, underfill 16 can comprise or be referred to as CUF, NCP, NCF, ACF, or ACP. In some examples, when electronic component 11 includes molded underfill (MUF), underfill 16 can be considered part of encapsulant 14.

In some examples, component interconnects 111 can be bonded to interposer interconnects 122. Component interconnects 111 can be bonded by solderless bond with interposer interconnects 122. Component interconnects 111 can be bonded with interposer interconnects 122 using thermocompression.

In some examples, after electronic component 11 is bonded to interposer 12, underfill 16 can be interposed between electronic component 11 and interposer 12 to then be cured. Underfill 16 can prevent electronic component 11 from being separated from interposer 12 against physical and chemical impacts.

FIG. 4D shows electronic device 20 at a later stage of manufacture. In the example shown in FIG. 4D, encapsulant 14 can be provided to cover electronic component 11, interposer 12, and underfill 16. Encapsulant 14 can be in contact with the lateral sides of electronic component 11, the upper side of interposer base 124, and the lateral sides of underfill 16.

Encapsulant 14 can comprise corresponding elements, features, materials, or manufacturing methods similar to those of encapsulant 14 shown in FIG. 2K. after forming encapsulant 14, carrier 19 can be separated from redistribution structure 13 and external interconnects 15. In some examples, a singulation process of sawing interposer 12, redistribution structure 13, and encapsulant 14 to separate it into electronic device 10 can be performed. In some examples, the singulation process can be performed by using a diamond blade or laser beam.

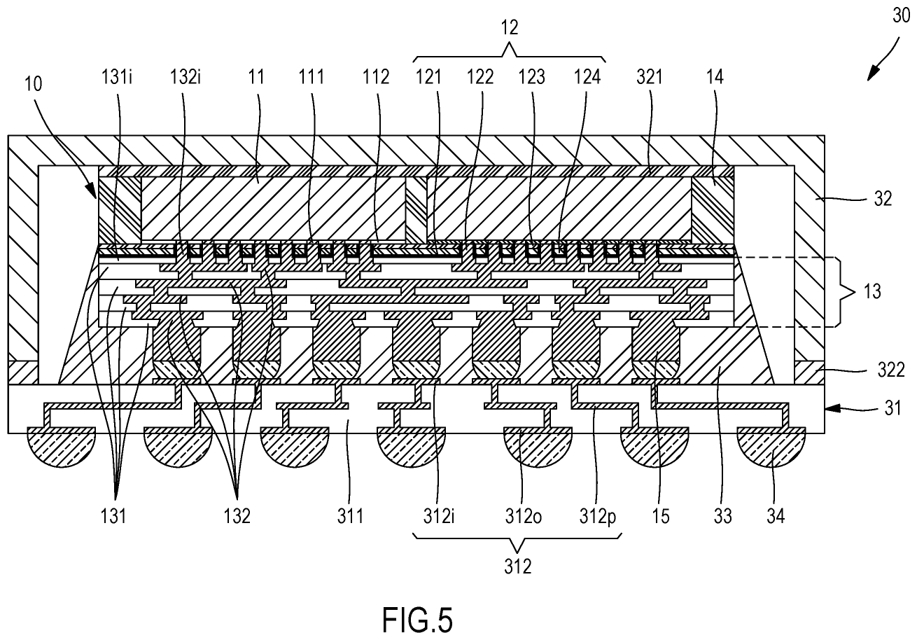

FIG. 5 shows a cross-sectional view of an example electronic device 30. In the example shown in FIG. 5, electronic device 30 can comprise electronic device 10, substrate 31, lead 32, second underfill 33, and device interconnects 34. Electronic device 30 can comprise electronic component 11, interposer 12, redistribution structure 13, encapsulant 14, and external interconnects 15. Electronic device 30 can comprise corresponding elements, features, materials, or manufacturing methods similar to or the same as those of electronic device 10 shown in FIGS. 1 and 2A to 2K.

Substrate 31 can comprise dielectric structure 311 and conductive structure 312. In some examples, dielectric structure 311 can comprise or be referred to as one or more dielectric layers. For instance, the one or more dielectric layers can comprise, one or more dielectric layers such as, a core layer, a polymer layers, pre-preg layers, or solder mask layers stacked on each other. One or more layers or elements of conductive structure 312 can be interposed or embedded between the one or more layers of dielectric structure 311. The upper and lower sides of dielectric structure 311 can be substrate inner side and substrate outer side of substrate 31, respectively. In some examples, dielectric structure 311 can comprise a polymer, polyimide (PI), benzocyclobutene (BCB), polybenzoxazole (PBO), bismaleimide triazine (BT), Ajinomoto Buildup Film (ABF) or resin. In some examples, the thickness of dielectric structure 311 can range from approximately 20 μm to 500 μm.

Conductive structure 312 can comprise one or more conductive layers and defines conductive paths with elements such as traces, pads, vias, and wiring patterns. Conductive structure 312 can comprise inward terminal 312i provided on substrate inner side of substrate 120, outward terminal 3120 provided on substrate outer side of substrate 120, and conductive path 312p extending through dielectric structure 311.

Inward terminal 312i and outward terminal 3120 can be respectively provided on substrate inner side and substrate outer side in a matrix form having rows or columns, respectively. In some examples, inward terminal 312i or outward terminal 3120 can comprise or be referred to as a conductor, a conductive material, a substrate land, a conductive land, a substrate pad, a wiring pad, a connection pad, a micro pad, or under-bump-metallurgy (UBM). The thicknesses of inward terminal 312i or outward terminal 3120 can range from approximately 1 μm to 50 μm. Inward terminal 312i can be in contact with and electrically connected to external interconnects 15 of electronic device 10.

Conductive path 312p can be provided in dielectric structure 311 to couple inward terminal 312i with outward terminal 3120. Conductive path 312p can be provided of one or more conductive layers. In some examples, conductive path 312p can comprise or be referred to as one or more conductors, conductive material, vias, circuit patterns, traces, or wiring patterns. In some examples, inward terminal 312i, outward terminal 3120, and conductive path 312p can comprise copper, iron, nickel, gold, silver, palladium, or tin.

In some examples, substrate 31 can comprise or be referred to as a rigid substrate, a flexible laminate substrate, a ceramic substrate, a glass substrate, a silicon substrate, a printed circuit board, a multilayer substrate, a laminate substrate, or a molded lead frame. In some examples, substrate 31 can comprise or be referred to as an RDL substrate, a buildup substrate, or a coreless substrate. In some example, Substrate 31 can have an area varying according to the area of electronic device 10 and can have an area of approximately 3 mm×3 mm to approximately 110 mm×110 mm. Substrate 120 can have a thickness varying according to the thickness of electronic device 10 and can have a thickness of approximately 0.1 mm to approximately 7 mm. In some examples, substrate 31 can comprise corresponding element, feature, material, or manufacturing method similar to those of redistribution structure 13.

Second underfill 33 can be located between electronic device 10 and substrate 31. Second underfill 33 can be interposed between the lower side of redistribution structure 13 of electronic device 10 and the upper side of substrate 31 and can surround the outer surfaces of external interconnects 15. Second underfill 33 can also be in contact with portions of sidewalls of electronic device 10. Second underfill 33 can comprise corresponding element, feature, material, or manufacturing method similar to those of underfill 16.

Lead 32 can be attached to the upper side of substrate 31 so as to surround electronic device 10. Lead 32 can comprise a substantially rectangular top plate and sidewalls extending downward from the edge of the top plate. Lead 32 can be attached and fixed to substrate 31 through adhesive 322 on the lower sides of sidewalls. Thermal interface material (TIM) 321 can be interposed between the top plate of lead 32 and the top surface of electronic device 10. Thermal interface material 321 can include a thermal conductive material and can be in contact with the upper side of electronic component 11 of electronic device 10 and the lower side of the top plate of lead 32. In some examples, thermal interface material 321 includes polymer type thermal interface materials, such as silicone, epoxy, or urethane with highly thermal conductive fillers, such as graphite, boron nitride, silver, aluminum, or aluminum oxide. Since thermal interface material 321 includes a thermally conductive material, heat generated in electronic component 11 of electronic device 10 can be easily transferred to lead 32. Lead 32 can have a thickness ranging from approximately 300 μm to 2000 μm. Thermal interface material 321 can have a thickness ranging from approximately 5 μm to 300 μm.

Device interconnects 34 can be in contact with or electrically connected to outward terminal 3120 of substrate 31. Electronic component 11 of electronic device 10 can be electrically connected to device interconnects 34 through interposer 12, redistribution structure 13, and substrate 31.

Device interconnects 34 can comprise corresponding elements, features, materials, or manufacturing methods similar to those of external interconnects 15.

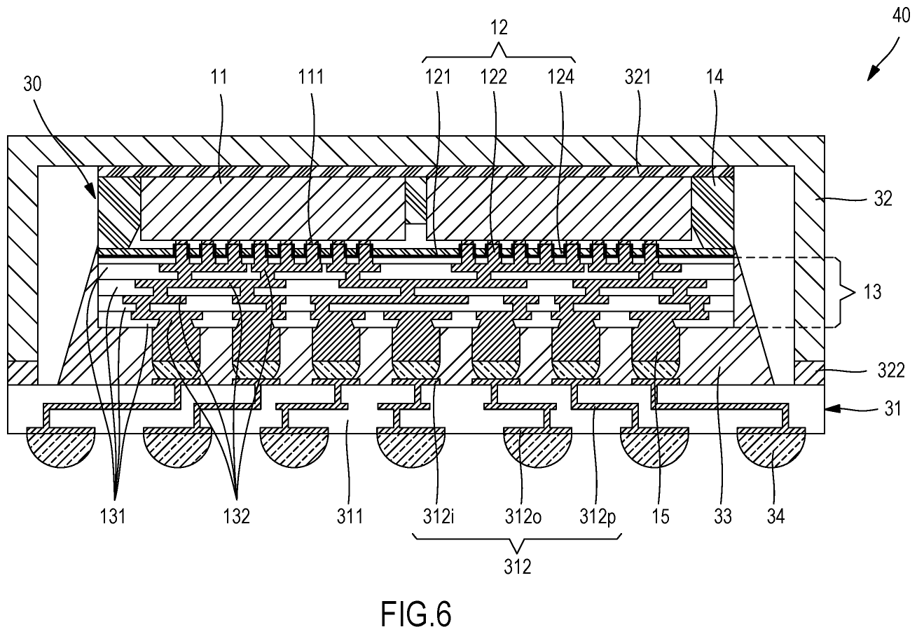

FIG. 6 shows a cross-sectional view of an example electronic device 40. In the example shown in FIG. 6, electronic device 40 can comprise electronic device 20, substrate 31, lead 32, second underfill 33, and device Interconnects 34. Electronic device 40 can comprise electronic component 11, interposer 12, redistribution structure 13, encapsulant 14, and external interconnects 15. In this example, electronic device 40 can comprise corresponding elements, features, materials, or manufacturing methods similar to those of electronic device 20 shown in FIGS. 3 and 4A to 4D. In this example, substrate 31, lead 32, second underfill 33, and device Interconnects 34 in electronic device 40 can comprise corresponding elements, features, materials, or manufacturing methods similar to those of electronic device 30 shown in FIG. 5.

Devices and methods of the present disclosure can support fine pitch integration with pitches of approximately 10 μm or finer. Interposers of the present disclosure can include silicon or glass substrate (e.g., interposer base 124) for improved support. The use of silicon or glass in an interposer tends to result in a more planarized surface than polymer-based construction techniques. Devices and methods of the present disclosure also tend to improve electrical performance by decreasing the contact thickness on electronic component 11 (e.g., thickness on μm scale with plating, or nanometer (nm) scale with sputtering). Thickness can also be reduced by using pad-free interposers of the present disclosure, which can reduce the length of the electrical path.

The present disclosure includes reference to certain examples, however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

1. A method of making an electronic device, comprising:
providing an interposer base including first side and a second side opposite the first side, wherein an inner wall of the interposer base defines an aperture in the first side;
providing a liner layer over the inner wall and the first side of the interposer base;
providing an interposer interconnect in the aperture;
providing a redistribution structure over the first side of the interposer base and the interposer interconnect, the redistribution structure comprising an organic material;
removing a portion of the interposer base from the second side to expose the liner layer;
providing an interposer passivation layer coupled to the liner layer and located around a sidewall of the interposer interconnect;
removing a portion of the of the liner layer to expose the interposer interconnect; and
providing an electronic component over the interposer base to bond a component interconnect of the electronic component to the interposer interconnect.

2. The method of claim 1, wherein the component interconnect is sputtered onto the electronic component.

3. The method of claim 2, wherein the component interconnect has a thickness less than approximately one micrometer.

4. The method of claim 1, wherein the component interconnect comprises copper, and wherein the interposer interconnect comprises copper.

5. The method of claim 1, further comprising providing a component passivation layer located around a sidewall of the component interconnect and comprising an inorganic material,
wherein the interposer passivation layer comprises the inorganic material, and
wherein the component passivation layer is bonded with the interposer passivation layer.

6. The method of claim 5, wherein a side of the component interconnect is recessed from a side of the component passivation layer before providing the electronic component.

7. The method of claim 1, further comprising removing a portion of the interposer interconnect protruding from the interposer passivation layer to form an upper side of the interposer interconnect, wherein the upper side of the interposer interconnect is recessed from the interposer passivation layer.

8. The method of claim 7, wherein the component interconnect is coupled to the interposer interconnect by a solderless bond.

9. The method of claim 1, wherein the liner layer is between the inner wall of the interposer base and the sidewall of the interposer interconnect.

10. The method of claim 1, wherein the interposer base is between the organic material of the redistribution structure and an inorganic material of the interposer passivation layer.

11. The method of claim 1, wherein a height of the interposer interconnect is approximately five micrometers above the second side of the interposer base.

12. The method of claim 1, wherein the interposer base comprises silicon or glass.

13. An electronic device, comprising:
an interposer base including inner walls defining openings through the interposer base;
a liner layer located on the inner walls and a first surface of the interposer base;
interposer interconnects located in the openings and coupled to the liner layer, wherein the interposer interconnects protrude from a first side of the interposer base;
a first electronic component comprising component interconnects bonded to the interposer interconnects;
an interposer passivation layer located on the first side of the interposer base and around the interposer interconnects; and
a redistribution structure located on a second side of the interposer base opposite the first side, wherein the redistribution structure comprises an organic material and is coupled to the interposer interconnects.

14. The electronic device of claim 13, wherein the interposer base comprises silicon or glass.

15. The electronic device of claim 13, wherein the component interconnects have a height less than approximately one micrometer from a side of the first electronic component.

16. The electronic device of claim 15, wherein a first interposer interconnect of the interposer interconnects protrudes less than approximately five micrometers from the first side of the interposer base.

17. The electronic device of claim 15, wherein the interposer passivation layer is located around the component interconnects and around the interposer interconnects.

18. The electronic device of claim 13, wherein the liner layer is between the inner walls of the interposer base and sidewalls of the interposer interconnects.

19. The electronic device of claim 13, wherein a thickness of the redistribution structure is greater than a thickness of the interposer base.

20. The electronic device of claim 13, further comprising:
a second electronic component coupled to the interposer base; and
an encapsulant located around the first electronic component and the second electronic component.
